(19) United States
(12) Patent Application Publication
(10) Pub. No.: US 2026/0358440 A1
(43) Pub. Date: Nov. 12, 2026

(54) VIBRATION MODULE

(71) Applicant: Primax Electronics Ltd., Taipei (TW)

(72) Inventors: Wei-Chiang Huang, Taipei (TW); Wei-Ping Chan, Taipei (TW); Tse-Ping Kuan, Taipei (TW); Ming-Hui Yeh, Taipei (TW)

(21) Appl. No.: 19/538,783

(22) Filed: Feb. 12, 2026

(30) Foreign Application Priority Data
May 6, 2025 (TW) 114117045

(51) Int. Cl. G01R 33/00; G06F 3/0354

(52) U.S. Cl. CPC G01R 33/0023; G06F 3/03547

(57) ABSTRACT

A vibration module includes a base plate, a magnetic sensor, a circuit board and a magnetic element. The base plate has a top surface. The magnetic sensor includes a periphery part. The circuit board includes a cutting edge. The magnetic sensor and the circuit board are installed on the top surface of the base plate. The periphery part of the magnetic sensor corresponds to the cutting edge of the circuit board. The magnetic element is located over the base plate and aligned with the magnetic sensor. The magnetic sensor and the circuit board are arranged parallel to each other and side by side and collaboratively formed as a magnetic sensing circuit layer. When a current flows to the magnetic sensor through the circuit board, the magnetic sensor is electrically conducted to sense a magnetism of the magnetic element and generate vibration.

### FIELD OF THE INVENTION

The present invention relates to an electromagnetic induction device, and more particularly to a vibration module.

### BACKGROUND OF THE INVENTION

Conventionally, a vibration module is operated according to the principle of electromagnetic induction. For example, a conductive coil interacts with the magnetic field of a magnet to cause vibration of the conductive coil or the magnet. During the operation of the vibration module, the vibration module drives other objects to vibrate together or transmitting the vibration to other structures. The vibration module is usually applied in touchpad modules or electronic input devices to provide users with tactile vibration feedback during operation.

Nowadays, as touchpad modules or electronic devices are gradually designed to be thinner, lighter and more compact, the position and size of the available internal space for accommodating vibration modules become increasingly limited. In particular, as the thickness of the touchpad module is reduced and the surface area is minimized, it is necessary to reduce the thickness, height and volume of the vibration module in order to meet the design requirements.

### SUMMARY OF THE INVENTION

For solving the drawbacks of the conventional technologies, the present invention provides a vibration module. The thickness of the components in the vibration module is reduced. In addition, some of the components are arranged in a staggered and side-by-side manner. Due to this arrangement, multiple components are assembled into a single layer on the same plane. When compared with the stacked component arrangement in the conventional technology, the thickness and the overall height of the vibration module of the present invention can be further reduced.

In accordance with an aspect of the present invention, a vibration module is provided. The vibration module includes a base plate, a magnetic sensor, a circuit board, a magnetic element and a top plate. The base plate has a top surface. The magnetic sensor is installed on the top surface of the base plate. The magnetic sensor includes a periphery part. The circuit board is installed on the top surface of the base plate and electrically connected with the magnetic sensor. The circuit board includes a cutting edge. The magnetic element is located over the base plate and aligned with the magnetic sensor. The top plate has a bottom surface. The top plate is located over the base plate. The bottom surface of the top surface is aligned with the magnetic element. The top plate covers the magnetic element and the magnetic sensor. The magnetic sensor and the circuit board are arranged parallel to each other and side by side and collaboratively formed as a magnetic sensing circuit layer. The magnetic sensing circuit layer is parallel to the base plate and installed on the top surface of the base plate. The periphery part of the magnetic sensor corresponds to the cutting edge of the circuit board. When a current flows to the magnetic sensor through the cutting edge of the circuit board, the magnetic sensor is electrically conducted to sense a magnetism of the magnetic element and generate vibration.

In an embodiment, the periphery part of the magnetic sensor and the cutting edge of the circuit board have the complementary shapes, and the periphery part of the magnetic sensor and the cutting edge of the circuit board are engaged with each other.

In an embodiment, the circuit board includes an edge region. After the edge region of the circuit board is cut according to a complementary shape of the periphery part of the magnetic sensor, the cutting edge of the circuit board is formed.

In an embodiment, the magnetic sensing circuit layer includes a magnetic sensing circuit plane. The magnetic sensing circuit plane is separated from the magnetic element. The magnetic sensing circuit plane and the magnetic element are parallel to each other.

In an embodiment, the magnetic sensor has a magnetic sensing surface, and the circuit board has a board surface. The magnetic sensing surface of the magnetic sensor and the board surface of the circuit board are parallel to each other and arranged side by side are formed as the magnetic sensing circuit plane.

In an embodiment, the circuit board includes a plurality of electrical contacts. The plurality of electrical contacts are installed on the board surface of the circuit board and electrically connected with the magnetic sensor.

In an embodiment, the magnetic sensor includes a plurality of conductive wires, and the plurality of conductive wires are electrically connected with the circuit board.

In an embodiment, the magnetic sensor is formed by winding conductive metal wires, and the plurality of conductive wires of the magnetic sensor are wire terminals of the conductive metal wires that are extended externally.

In an embodiment, the vibration module further includes a frame with a groove. The frame is arranged between the top plate and the magnetic element and coupled to the bottom surface of the top plate. The magnetic element is disposed within the groove of the frame.

In an embodiment, a thickness of the magnetic sensing circuit layer is in a range between 0.08 mm and 0.15 mm.

In an embodiment, a thickness of the magnetic element is in a range between 0.3 mm and 0.8 mm.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic perspective view illustrating a vibration module according to an embodiment of the present invention;

FIG. 2 is a schematic side view illustrating the vibration module according to the embodiment of the present invention;

FIG. 3 is a schematic exploded view illustrating the vibration module according to the embodiment of the present invention;

FIG. 4 is a schematic cross-sectional view illustrating the vibration module according to the embodiment of the present invention;

FIG. 5 is a schematic top view illustrating the relationship between the magnetic sensor and the circuit board of the vibration module according to the embodiment of the present invention;

FIG. 6 is a schematic top view illustrating the relationship between the magnetic sensor, the circuit board and the magnetic element of the vibration module according to the embodiment of the present invention; and

FIG. 7 is a schematic side view illustrating the relationship between the magnetic element and the magnetic sensing circuit layer of the vibration module according to the embodiment of the present invention.

### DETAILED DESCRIPTION OF THE PREFERRED EMBODIMENT

The present invention will now be described more specifically with reference to the following embodiments and accompanying drawings.

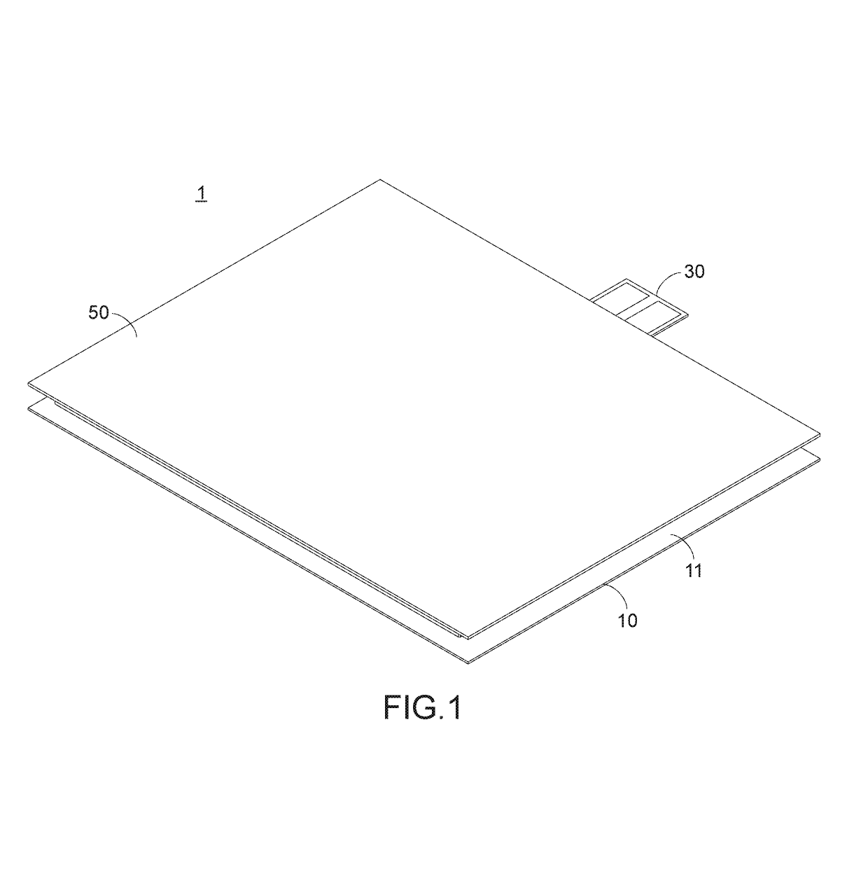

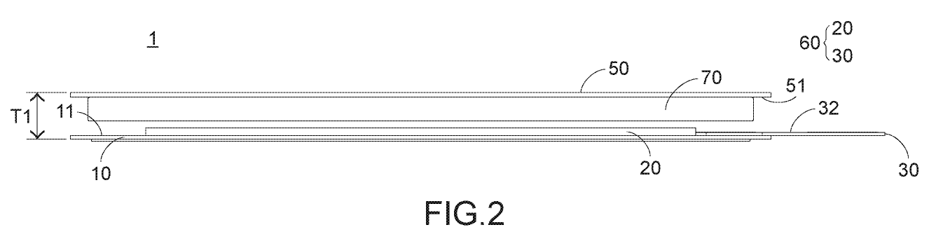

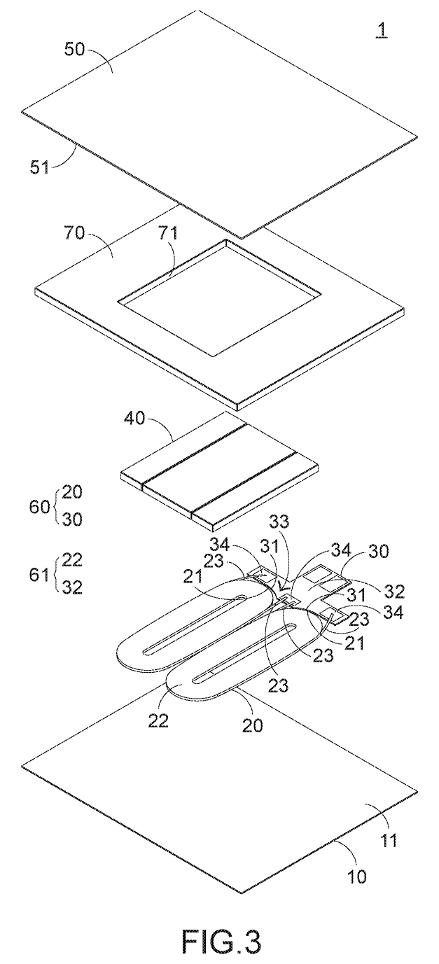

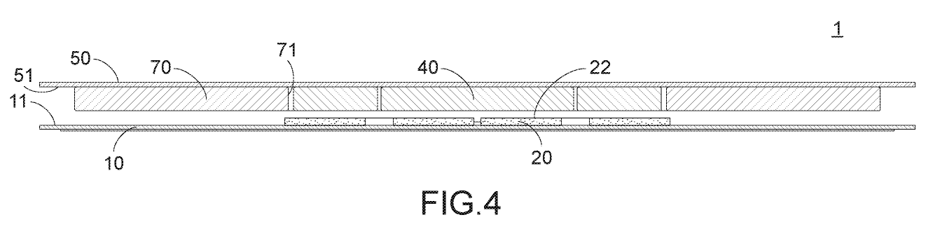

FIG. 1 is a schematic perspective view illustrating a vibration module according to an embodiment of the present invention. FIG. 2 is a schematic side view illustrating the vibration module according to the embodiment of the present invention. FIG. 3 is a schematic exploded view illustrating the vibration module according to the embodiment of the present invention. FIG. 4 is a schematic cross-sectional view illustrating the vibration module according to the embodiment of the present invention.

In an embodiment, the vibration module 1 includes a base plate 10, a magnetic sensor 20, a circuit board 30, a magnetic element 40 and a top plate 50. The magnetic sensor 20 and the circuit board are arranged parallel to each other and side by side and collaboratively formed as a magnetic sensing circuit layer 60. The vibration module 1 may further include a frame 70. The frame 70 includes a groove 71.

The base plate 10 has a top surface 11. The magnetic sensor 20 includes a periphery part 21, a magnetic sensing surface 22 and a plurality of conductive wires 23. The circuit board 30 includes a cutting edge 31, a board surface 32, an edge region 33, and a plurality of electrical contacts 34. The top plate 50 has a bottom surface 51.

The magnetic sensor 20 is installed on the top surface 11 of the base plate 10. The circuit board 30 is installed on the top surface 11 of the base plate 10 and electrically connected with the magnetic sensor 20. The magnetic element 40 is located over the base plate 10 and aligned with the magnetic sensor 20. The top plate 50 is located over the base plate 10. In addition, the bottom surface 51 of the top plate 50 faces the magnetic element 40. The top plate 50 covers the magnetic element 40 and the magnetic sensor 20.

In an embodiment, the magnetic element 40 can be directly coupled to the bottom surface 51 of the top plate 50. Alternatively, the frame 70 is arranged between the top plate 50 and the magnetic element 40, then the frame 70 is coupled to the bottom surface 51 of the top plate 50, and finally the magnetic element 40 is disposed within the groove 71 of the frame 70. In this embodiment, the frame 70 is coupled to the bottom surface 51 of the top plate 50, and the magnetic element 40 is disposed within the groove 71 of the frame 70. For example, the magnetic element 40 includes a single magnet or two magnets arranged side by side. Alternatively, the magnetic element 40 includes a plurality of magnets arranged in a Halbach array.

The magnetic sensing circuit layer 60, which is the combination of the magnetic sensor 20 and the circuit board 30, is parallel to the base plate 10. In addition, the magnetic sensing circuit layer 60 is installed on the top surface 11 of the base plate 10. The periphery part 21 of the magnetic sensor 20 corresponds to the cutting edge 31 of the circuit board 30. When a current flows to the magnetic sensor 20 through the cutting edge 31 of the circuit board 30, the magnetic sensor 20 is electrically conducted to sense the magnetism of the magnetic element 40 and generate vibration accordingly.

Preferably, the overall thickness T1 of the vibration module 1 is less than 1.5 mm. The structural technology for reducing the thickness of the vibration module will be described in detail as follows.

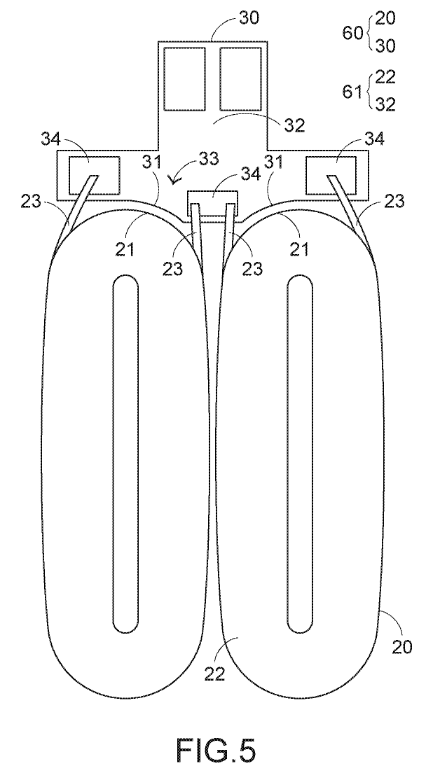

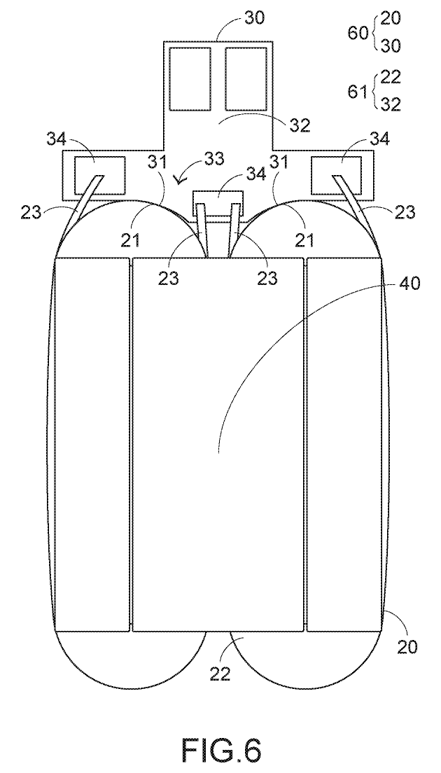

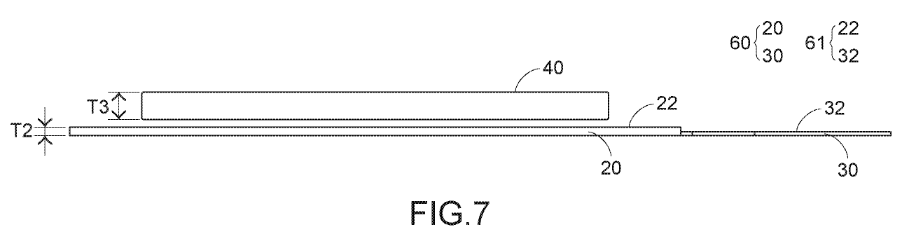

FIG. 5 is a schematic top view illustrating the relationship between the magnetic sensor and the circuit board of the vibration module according to the embodiment of the present invention. FIG. 6 is a schematic top view illustrating the relationship between the magnetic sensor, the circuit board and the magnetic element of the vibration module according to the embodiment of the present invention. FIG. 7 is a schematic side view illustrating the relationship between the magnetic element and the magnetic sensing circuit layer of the vibration module according to the embodiment of the present invention.

The magnetic sensor 20 and the circuit board 30 are both disposed on the same surface 11 of the same base plate 10. In addition, the magnetic sensor 20 and the circuit board 30 are arranged side by side on the top surface 11 of the base plate 10 and collaboratively formed as the magnetic sensing circuit layer 60.

The shape of the periphery part 21 of the magnetic sensor 20 and the shape of the cutting edge 31 of the circuit board 30 are complementary to each other and are engageable with each other. As shown in FIG. 5, the edge region 33 of the circuit board 30 corresponds to the periphery part 21 of the magnetic sensor 20. After the edge region 33 of the circuit board 30 is cut according to the complementary shape of the periphery part 21 of the magnetic sensor 20, the cutting edge 31 of the circuit board 30 can be formed. In this way, the periphery part 21 of the magnetic sensor 20 and the cutting edge 31 of the circuit board 30 have the complementary shapes. As clearly shown in FIG. 6, the periphery part 21 of the magnetic sensor 20 and the cutting edge 31 of the circuit board 30 are engaged with each other. Consequently, the magnetic sensor 20 and the circuit board 30 are coplanar with each other. Since these two elements are not overlapped and covered by each other, the thickness will not be increased.

As mentioned above, the magnetic sensor 20 and the circuit board 30 are collaboratively formed as the magnetic sensing circuit layer 60. The magnetic sensing circuit layer 60 has a magnetic sensing circuit plane 61. The magnetic sensing circuit plane 61 is separated from the magnetic element 40. In addition, the magnetic sensing circuit plane 61 and the magnetic element 40 are parallel to each other. The magnetic sensing circuit plane 61 can sense the magnetism of the magnetic element 40 and thus generate vibration. Since the magnetic sensor 20 and the circuit board 30 are arranged parallel to each other and side by side, the magnetic sensing surface 22 of the magnetic sensor 20 and the board surface 32 of the circuit board 30 are also arranged parallel to each other and side by side. Due to this structural design, the magnetic sensing surface 22 of the magnetic sensor 20 and the board surface 32 of the circuit board 30 are extended and combined as the magnetic sensing circuit plane 61. As a consequently, the magnetic sensing area is extended and expanded.

The plurality of electrical contacts 34 of the circuit board 30 are installed on the board surface 32 of the circuit board 30. In addition, the plurality of electrical contacts 34 are located at the edge region 33 of the circuit board 30 and located adjacent to the cutting edge 31 of the circuit board 30. The electrical contacts 34 are electrically connected with the magnetic sensor 20. The plurality of conductive wires 23 of the magnetic sensor 20 are extended externally from the periphery part 21 of the magnetic sensor 20 and electrically connected with corresponding electrical contacts 34 of the circuit board 30.

Preferably, the magnetic sensor 20 is formed by winding conductive metal wires. Consequently, the conductive wires 23 of the magnetic sensor 20 are wire terminals that are extended externally from the periphery part 21 of the magnetic sensor 20.

Please refer to FIG. 7. The thickness T2 of the magnetic sensing circuit layer 60 is in the range between 0.08 mm and 0.15 mm. The thickness T3 of the magnetic element 40 is in the range between 0.3 mm and 0.8 mm. The total physical thickness of the main components that produce the magnetic induction vibration effect, i.e., the magnetic sensing circuit layer 60 and the magnetic element 40, can be reduced to less than 0.95 mm. The sum of the total thickness of the magnetic sensing circuit layer 60 and the magnetic element 40, the height between the magnetic sensing circuit layer 60 and the magnetic element 40, the thickness of the base plate 10 and the thickness of the top plate 50 is equal to the thickness T1 (shown in FIG. 2) of the vibration mode 2 is up to 1.5 mm. Furthermore, if the height between the magnetic sensing circuit layer 60 and the magnetic element 40 is changed or the thickness of the base plate 10 or the thickness of the top plate 50 is reduced, the thickness T1 of the vibration module can be further reduced to less than 1.5 mm. Consequently, the overall thickness and height of the vibration module are reduced, and the volume of the vibration module is decreased.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all modifications and similar structures.

What is claimed is:

1. A vibration module, comprising:
a base plate having a top surface;
a magnetic sensor installed on the top surface of the base plate, wherein the magnetic sensor comprises a periphery part;
a circuit board installed on the top surface of the base plate, and electrically connected with the magnetic sensor, wherein the circuit board comprises a cutting edge;
a magnetic element located over the base plate, and aligned with the magnetic sensor; and
a top plate having a bottom surface, wherein the top plate is located over the base plate, the bottom surface of the top surface is aligned with the magnetic element, and the top plate covers the magnetic element and the magnetic sensor,
wherein the magnetic sensor and the circuit board are arranged parallel to each other and side by side and collaboratively formed as a magnetic sensing circuit layer, and the magnetic sensing circuit layer is parallel to the base plate and installed on the top surface of the base plate,
wherein the periphery part of the magnetic sensor corresponds to the cutting edge of the circuit board,
wherein when a current flows to the magnetic sensor through the cutting edge of the circuit board, the magnetic sensor is electrically conducted to sense a magnetism of the magnetic element and generate vibration.

2. The vibration module according to claim 1, wherein the periphery part of the magnetic sensor and the cutting edge of the circuit board have the complementary shapes, and the periphery part of the magnetic sensor and the cutting edge of the circuit board are engaged with each other.

3. The vibration module according to claim 2, wherein the circuit board comprises an edge region, wherein after the edge region of the circuit board is cut according to a complementary shape of the periphery part of the magnetic sensor, the cutting edge of the circuit board is formed.

4. The vibration module according to claim 1, wherein the magnetic sensing circuit layer comprises a magnetic sensing circuit plane, wherein the magnetic sensing circuit plane is separated from the magnetic element, and the magnetic sensing circuit plane and the magnetic element are parallel to each other.

5. The vibration module according to claim 4, wherein the magnetic sensor has a magnetic sensing surface, and the circuit board has a board surface, wherein the magnetic sensing surface of the magnetic sensor and the board surface of the circuit board are parallel to each other and arranged side by side are formed as the magnetic sensing circuit plane.

6. The vibration module according to claim 5, wherein the circuit board includes a plurality of electrical contacts, wherein the plurality of electrical contacts are installed on the board surface of the circuit board and electrically connected with the magnetic sensor.

7. The vibration module according to claim 1, wherein the magnetic sensor comprises a plurality of conductive wires, and the plurality of conductive wires are electrically connected with the circuit board.

8. The vibration module according to claim 7, wherein the magnetic sensor is formed by winding conductive metal wires, and the plurality of conductive wires of the magnetic sensor are wire terminals of the conductive metal wires that are extended externally.

9. The vibration module according to claim 1, wherein the vibration module further comprises a frame with a groove, wherein the frame is arranged between the top plate and the magnetic element and coupled to the bottom surface of the top plate, and the magnetic element is disposed within the groove of the frame.

10. The vibration module according to claim 1, wherein a thickness of the magnetic sensing circuit layer is in a range between 0.08 mm and 0.15 mm.

11. The vibration module according to claim 1, wherein a thickness of the magnetic element is in a range between 0.3 mm and 0.8 mm.
